(19) United States
(12) Patent Application Publication
(10) Pub. No.: US 2023/0128538 A1
(43) Pub. Date: Apr. 27, 2023

(54) LED LAMP STRING AND PROCESSING TECHNIQUE THEREOF

(71) Applicant: LINHAI DAFAN ELECTRONIC & TECHNOLOGICAL CO.,LTD, Zhejiang (CN)

(72) Inventor: Cheng Lu, Zhejiang (CN)

(73) Assignee: LINHAI DAFAN ELECTRONIC & TECHNOLOGICAL CO.,LTD, Zhejiang (CN)

(21) Appl. No.: 17/509,071

(22) Filed: Oct. 25, 2021

(51) Int. Cl. F21S 4/10; F21V 23/00; F21K 9/90

(52) U.S. Cl. CPC F21S 4/10; F21K 9/90; F21V 23/001; F21Y 2115/10

(57) ABSTRACT

The disclosure relates to an LED lamp string and a processing technique thereof, the LED lamp string including an anode wire, a cathode wire and several LED light emitting patches. Anodes and cathodes of the LED light emitting patches are directly connected to the anode wire and the cathode wire respectively. The LED light emitting patches, a portion of the anode wire located proximate to the LED light emitting patches, and a portion of the cathode wire located proximate to the LED light emitting patches directly complete entire cladding through a modeling lamp bead, and the LED light emitting patches each includes at least one LED light emitting patch unit. The disclosure uses a patch connecting structure for a direct connection to a wire, without needing a pin bracket. In addition, encapsulating is completed directly through the modeling lamp bead and a wire is used to replace a pin.

### BACKGROUND

### Technical Field

The present invention relates to the technical field of LED and in particular, relates to an LED lamp string.

### Description of Related Art

A light emitting diode is known as a Light Emitting Diode (abbreviated as LED) in English as a new solid light source. Born in the 1960s, the light emitting diode was developed by Lossen o. w. in 1923 while studying a semiconductor SiC, finding light emitted in an impure P-N junction. However, it had not been focused on. With the rapid development of the electronic industry, a display technique has realized rapid development in the 1960s, due to which LED catches increasing attention of people gradually. LED has following advantages: a long service life ( > 100,000 Hrs), a lower driving voltage (1.8 ~4.5 V), less power consumption (40~ 1000 mW), being small and fast in lighting speed relative cold light source radiation (a time constant is 10-7 ~ 10-9 S), avoiding of a suspected lighting effect, small volume, multiple colors, favorable resistance to shock (it is not easy to cause damage because of full-solid encapsulating), favorable monochromaticity (its light emitting wavelength is stable) and being green and free from pollution.

An LED lamp string is formed by completing connection of a plurality of LED lamp beads and is generally used for decorations of Christmas Day and other festivals and applied to home decorations, city lighting engineering and various entertainment and activity places. The LED lamp string has incomparable advantages as compared with a conventional filament lamp string, because of its bright color. Therefore, various changes of color can be realized and energy consumption can be effectively reduced. A seven-color-variable lamp string formed not only performs a lighting function. Further, its decorating function adds the atmosphere of happiness for different programs on different occasions. However, an LED lamp bead is generally a direct-inserting LED lamp bead and as shown in FIG. 4, comprises two thin and long pin brackets, which are connected to LED light emitting elements. Then, a part of the pin brackets and the LED light emitting elements is encapsulated through epoxy resin and other materials, thereby forming a modeling lamp bead. Thus, an entire LED lamp bead is formed. However, as such a product has higher requirements on molding accuracy of a pin and is affected by a cup forming accuracy (a portion connected to an LED light emitting element) of the pin in an automatic production, consistency of color and brightness of the direct-inserting LED is caused to be poor. In addition, an encapsulating structure of an LED lamp in the prior art involves mounting an LED chip to a mounting LED bracket. Then, through a mold top device, a mold top of a special-purpose LED mold top encapsulating adhesive is molded on the LED bracket, or through the manner of spot-adhesive molding, the LED molding silicon rubber is spotted on the LED bracket, such that the mold top on the LED bracket is molded into an LED lens and an LED chip is encapsulated on the LED bracket. The steps and working procedures of changing brackets can be completed only with independent LED brackets.

### SUMMARY

The objective of the present invention is to provide an LED lamp string to solve the above technical problem, the LED lamp string having such features as convenient processing, favorable light emitting consistency of LED and low manufacturing cost.

The technical problem to be solved in the present invention can be implemented with the following technical solution:

an LED lamp string, comprising a wire body and several LED light emitting patches, wherein anodes and cathodes of the LED light emitting patches are directly and electrically connected to an anode wire and a cathode wire in the wire body respectively, the LED light emitting patches, and a portion of the wire body located proximate to the LED light emitting patches complete encapsulating and directly complete entire cladding through a modeling lamp bead, and the LED light emitting patches each comprises at least one LED light emitting patch unit.

The LED light emitting patches are each located at a corer portion of the anode wire and the cathode wire and arranged as an inverted U, and two sides of the anode wire and the cathode wire extend respectively to an outer side at a bottom of the modeling lamp bead.

The LED light emitting patches are each located at a corner portion of the anode wire and the cathode wire.

Several modeling lamp beads cladded with LED light emitting patches are in a serial connection.

The wire body further comprises an address writing wire, and the address writing wire is in a side-by-side arrangement with respect to the anode wire and the cathode wire.

The wire body is one of a copper wire, a silver wire and a copper enameled wire.

The modeling lamp bead has one or more shapes of a round head, an ellipse, a concave, a bullet, a straw hat, a diamond and a polygon.

A light emitting plate inside each of the LED light emitting patches faces toward a top end of the modeling lamp bead.

An insulating layer covers an outer surface of the wire body.

The insulating layer is made of one of a resin, a plastic material and a silicon rubber.

The single modeling lamp bead is used to clad two LED light emitting patch units.

The single modeling lamp bead is used to clad three LED light emitting patch units.

A processing technique of an LED lamp string comprises S1: using a photoelectric color scanner to sort an LED light emitting patch unit and completing sorting for the LED light emitting patch unit in a corresponding color according to technical requirements;

S2: mounting the LED light emitting patch unit in the corresponding color to a conductive portion on an anode wire, a cathode wire and an address writing wire inside a wire body through an LED mounting machine, thereby forming an electrical connection;

S3: completing smearing of a solder paste through a solder paste printer and disposing several contact surfaces for the wire body through grinding or cutting, wherein the contact surfaces each is a conductive surface and the solder paste is smeared on the contact surface;

S4: by combining the mounting machine in the step S2, docking an anode contact surface and a cathode contact surface that are smeared with the solder paste to an anode end and a cathode end of the LED light emitting patch unit and heating to fusion of the solder paste and then performing cooling to enable the anode wire to be welded to the anode end of the LED light emitting patch unit for being fixed and the cathode wire to be welded to the cathode end of the LED light emitting patch unit for being fixed; and

S5: after completing the welding, connecting a plurality of LED light emitting patch units on the anode wire and the cathode wire, the plurality of LED light emitting patch units being divided into several LED light emitting patches, then embedding a single LED or a plurality of light emitting patches and a portion of the wire body into a modeling chamber inside an injection mold; obtaining a modeling lamp bead through an injection, and completing encapsulating for a single LED light emitting patch and the anode wire and the cathode wire located proximate to two ends of the LED light emitting patch, thus obtaining an entire LED lamp string.

The present invention uses a patch connecting structure for a direct connection to a wire, without needing a pin bracket, thereby increasing convenience and speed of processing and also creating advantages for sorting LED colors to improve light emitting consistency. In addition, encapsulating is completed directly through the modeling lamp bead and a wire is used to replace a pin to reduce processing procedures and lower processing cost while ensuring beauty to an appearance of the modeling lamp bead.

The features of the present invention can be clearly understood by referring to drawings thereof and detailed descriptions of the following preferable embodiments.

### BRIEF DESCRIPTION OF THE DRAWINGS

FIG. 1 is a schematic diagram of a decomposition structure in the present invention;

FIG. 2 is a No. 1 schematic diagram of an entire structure in the present invention;

FIG. 3 is a No. 2 schematic diagram of an entire structure in the present invention; and

FIG. 4 is a schematic diagram of an entire structure for the prior technical product;

wherein, 1 denotes anode wire; 2, cathode wire; 3, modeling lamp bead; and 4, LED light emitting patch unit.

### DESCRIPTION OF THE EMBODIMENTS

In order to make the technical means, creative features, achievement goals and effects achieved by the present invention easy to understand, the present invention will be further described below in conjunction with specific illustrations.

### Embodiment 1

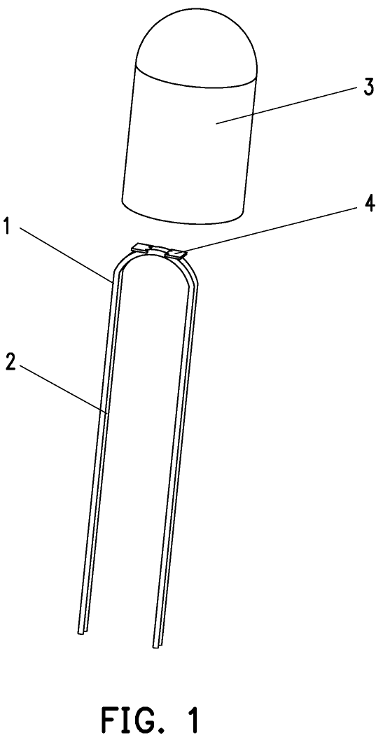

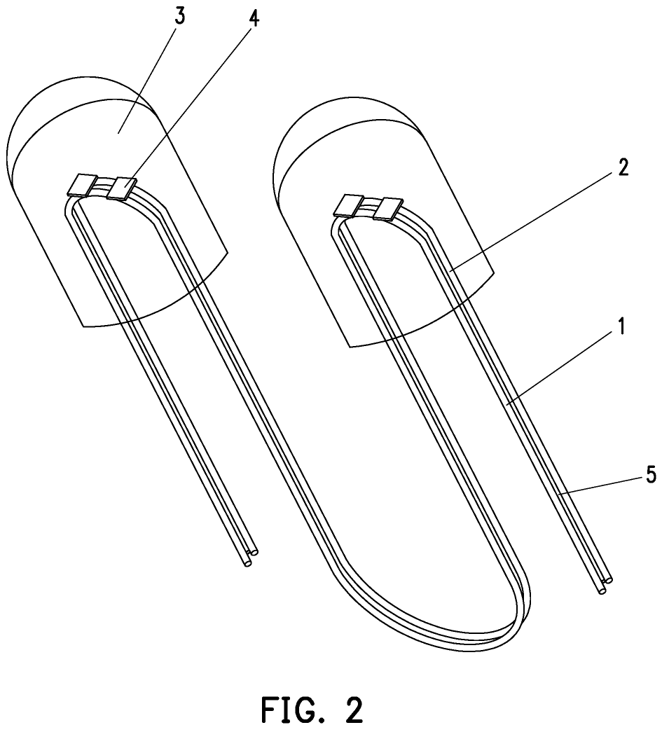

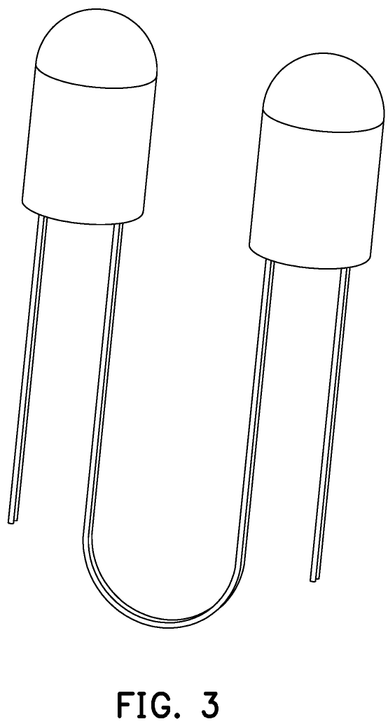

As shown in FIGS. 1 to 3, the embodiment discloses an LED lamp string comprising a wire body and several LED light emitting patches, wherein the wire body comprises an anode wire and a cathode wire, anodes and cathodes of the LED light emitting patches are directly connected to the anode wire and the cathode wire respectively, the LED light emitting patches, a portion of the anode wire located proximate to the LED light emitting patches, and a portion of the cathode wire located proximate to the LED light emitting patches complete entire cladding through a modeling lamp bead, and the LED light emitting patches each comprises at least one LED light emitting patch unit.

In the above structure, an existing LED mounting machine is used to complete connection of the LED light emitting patches to the anode wire and the cathode wire, wherein there are generally two LED light emitting patch units in a preferable single modeling lamp bead.

Preferably, the LED light emitting patches are each located at a corer portion of the anode wire and the cathode wire and arranged as an inverted U, and two sides of the anode wire and the cathode wire extend respectively to an outer side at a bottom of the modeling lamp bead.

Preferably, several modeling lamp beads cladded with LED light emitting patches are in a serial connection.

Preferably, both the anode wire and the cathode wire are one or more of a copper wire, a silver wire and a copper enameled wire and an insulating coating covers an outer surface of the anode wire and the cathode wire, which are generally insulating wires commonly used in the prior art. The insulating coating is generally made of resin, plastic, silicon rubber and PVC etc.

According to materials of wires, the LED lamp string can form a copper wire lamp, a silver wire lamp and a flexible wire lamp etc.

Preferably, the modeling lamp bead has one or more shapes of a round head, an ellipse, a concave, a bullet, a straw hat, a diamond and a polygon.

Preferably, a light emitting plate inside each of the LED light emitting patches faces toward a top end of the modeling lamp bead.

Preferably, the single modeling lamp bead is used to clad two LED light emitting patch units.

Preferably, the single modeling lamp bead is used to clad three LED light emitting patch units.

By optimizing the product structure, processing procedures of the product are simplified, and processing cost is reduced. Meanwhile, production efficiency is improved.

The present invention uses a patch connecting structure for a direct connection to a wire, without needing a pin bracket, thereby increasing convenience and speed of processing and creating advantages for sorting LED colors to improve light emitting consistency. In addition, encapsulating is completed directly through the modeling lamp bead and a wire is used to replace a pin to reduce processing procedures and lower processing cost while ensuring beauty to an appearance of the modeling lamp bead.

### Embodiment 2

The embodiment discloses an LED lamp string comprising a wire body and several LED light emitting patches, wherein the wire body comprises an anode wire, a cathode wire and an address writing wire, anodes and cathodes of the LED light emitting patches are directly connected to the anode wire and the cathode wire respectively, the LED light emitting patches, a portion of the anode wire located proximate to the LED light emitting patches, a portion of the cathode wire located proximate to the LED light emitting patches and a portion of the address writing wire located proximate to the LED light emitting patches complete entire cladding directly through a modeling lamp bead, and the LED light emitting patches each comprises at least one LED light emitting patch unit.

Wherein, the address writing wire is in a side-by-side arrangement with respect to the anode wire and the cathode wire.

Wherein, the address writing wire is used for realizing address writing input of the LED lamp string, an insulating layer covers an outer surface of the anode wire, the cathode wire and the address writing wire and the insulating coating is generally made of resin, plastic, silicon rubber and PVC etc.

According to materials of wires, the LED lamp string can form a copper wire lamp, a silver wire lamp and a flexible wire lamp etc.

### Embodiment 3

Based on the above embodiments, according to different wire bodies, the embodiment discloses a processing technique of an LED lamp string, comprising:

S1: using a photoelectric color scanner to sort an LED light emitting patch unit and completing sorting for the LED light emitting patch unit in a corresponding color according to technical requirements;

S2: mounting the LED light emitting patch unit in the corresponding color to a wire body through an LED mounting machine, the wire body being divided into an anode wire and a cathode wire or an anode wire, a cathode wire and an address writing wire; wherein the wire body is selected at the step according to specific requirements of the LED lamp string;

S3: smearing a solder paste on the wire body through a solder paste printer and disposing several contact surfaces on the wire body through grinding or cutting, wherein the contact surfaces each is a conductive surface and the solder paste is smeared on the contact surface;

S4: by combining the mounting machine in the step S2, docking an anode contact surface and a cathode contact surface that are smeared with the solder paste to an anode end and a cathode end of the LED light emitting patch unit and heating to fusion of the solder paste and then performing cooling to enable the anode wire to be welded to the anode end of the LED light emitting patch unit for being fixed and the cathode wire to be welded to the cathode end of the LED light emitting patch unit for being fixed; and

S5: after completing the welding, connecting a plurality of LED light emitting patch units on the anode wire and the cathode wire, the plurality of LED light emitting patch units being divided into several LED light emitting patches, then embedding a single LED or a plurality of light emitting patches, and the anode wire and the cathode wire located proximate to two ends of the LED light emitting patch into a modeling chamber inside an injection mold; obtaining a modeling lamp bead through an injection, and completing encapsulating for a single LED light emitting patch and the anode wire and the cathode wire located proximate to two ends of the LED light emitting patch, thus obtaining an entire LED lamp string.

Wherein, the number of the LED light emitting patches is an integer multiple of the LED light emitting patch units, generally twice.

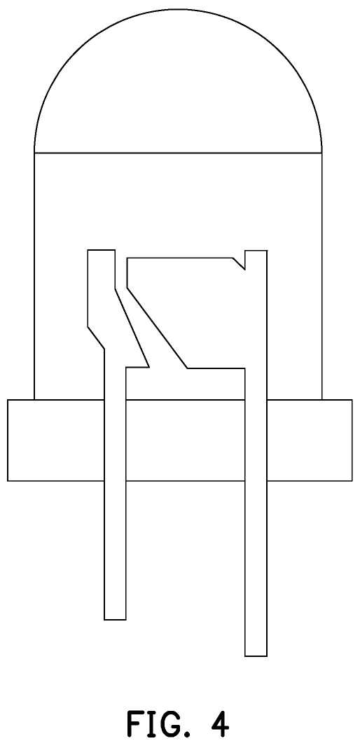

By optimizing the processing technique, processing and molding of the LED lamp bead in the product are of great difference from those of a conventional LED lamp bead (for example FIG. 4). The existing LED light emitting patch in a mounting structure is generally used on an FPC plate or a PCB to form a lamp strip or lamp bar. By optimizing the design, the LED light emitting patch unit performs processing of a modeling lamp bead, thus forming an LED lamp bead having a structure of the modeling lamp bead. Moreover, in the processing procedure, color sorting can be performed in early period. Then, the anode wire and the cathode wire can be used to realize welding of the anode and the cathode. Further, after bending is performed, injection is directly performed to form the modeling lamp bead. In this case, the processing steps are less, the production cost is lower and color sorting facilitates overall planning.

### Embodiment 4

Using the existing lamp ironing device, the products in embodiment 1 and embodiment 2 can be completed at pre-processing and a copper wire lamp, a silver wire lamp and a flexible wire lamp are directly formed. The LED lamp string of such a type does not have a modeling lamp bead in a conventional modeling design, as external encapsulating is directly completed therefor and then by combining the step S5 in the embodiment 3, a site of the LED light emitting patch unit whose encapsulating is completed is embedded as a whole into a modeling chamber inside an injection mold, and a modeling lamp bead is obtained through an injection.

It can be known from the common technical knowledge that the present invention can be implemented by other embodiments which are not separated from spiritual essence or necessary features of the present invention. Therefore, the above-disclosed embodiments are merely illustrative and not exclusive in all respects. All changes which are within the scope of the present invention or equivalent to the scope of the present invention are encompassed by the present invention.

1. An LED lamp string, comprising a wire body and several LED light emitting patches, wherein anodes and cathodes of the LED light emitting patches are directly and electrically connected to an anode wire and a cathode wire in the wire body respectively, the LED light emitting patches, and a portion of the wire body located proximate to the LED light emitting patches are encapsulated by a lamp bead, and the LED light emitting patches each comprises at least one LED light emitting patch unit,
wherein the LED lamp string is capable of forming a copper wire lamp, a silver wire lamp or a flexible wire lamp.

2. The LED lamp string according to claim 1, wherein the LED light emitting patches are each located at a corer portion of the anode wire and the cathode wire and arranged as an inverted U, and two sides of the anode wire and the cathode wire extend respectively to an outer side at a bottom of the lamp bead.

3. The LED lamp string according to claim 2, wherein the LED light emitting patches are each located at a corner portion of the anode wire and the cathode wire.

4. The LED lamp string according to claim 3, wherein several lamp beads cladded with LED light emitting patches are in a serial connection.

5. The LED lamp string according to claim 1, wherein the wire body further comprises an address writing wire, and the address writing wire is in a side-by-side arrangement with respect to the anode wire and the cathode wire.

6. The LED lamp string according to claim 1, wherein the wire body is one of a copper wire, a silver wire and a copper enameled wire.

7. The LED lamp string according to claim 1, wherein the lamp bead has one or more shapes of a round head, an ellipse, a concave, a bullet, a straw hat, a diamond and a polygon.

8. The LED lamp string according to claim 1, wherein a light emitting plate inside each of the LED light emitting patches faces toward a top end of the lamp bead.

9. The LED lamp string according to claim 1, wherein an insulating layer covers an outer surface of the wire body.

10. The LED lamp string according to claim 9, wherein the insulating layer is made of one of a resin, a plastic material and a silicon rubber.

11. The LED lamp string according to claim 10, wherein the single lamp bead is used to clad two LED light emitting patch units.

12. The LED lamp string according to claim 10, wherein the single lamp bead is used to clad three LED light emitting patch units.

13. A processing technique of an LED lamp string, comprising:
S1: using a photoelectric color scanner to sort an LED light emitting patch unit and completing sorting for the LED light emitting patch unit in a corresponding color according to technical requirements;
S2: mounting the LED light emitting patch unit in the corresponding color to a conductive portion on an anode wire, a cathode wire and an address writing wire inside a wire body through an LED mounting machine, thereby forming an electrical connection;
S3: by combining the mounting machine in the step S2, completing smearing of a solder paste through a solder paste printer, and disposing several contact surfaces for the wire body through grinding or cutting, wherein the contact surfaces each is a conductive surface and the solder paste is smeared on the contact surface;
S4: docking an anode contact surface and a cathode contact surface that are smeared with the solder paste to an anode end and a cathode end of the LED light emitting patch unit and heating to fusion of the solder paste and then performing cooling to enable the anode wire to be welded to the anode end of the LED light emitting patch unit for being fixed and the cathode wire to be welded to the cathode end of the LED light emitting patch unit for being fixed; and
S5: after completing the welding, connecting a plurality of LED light emitting patch units on the anode wire and the cathode wire, the plurality of LED light emitting patch units being divided into several LED light emitting patches, then embedding a single LED or a plurality of light emitting patches and a portion of the wire body into a modeling chamber inside an injection mold; obtaining a modeling lamp bead through an injection, and completing encapsulating for a single LED light emitting patch and the anode wire and the cathode wire located proximate to two ends of the LED light emitting patch, thus obtaining an entire LED lamp string.
